(19) United States
(12) Patent Application Publication
(10) Pub. No.: US 2009/0111062 A1
(43) Pub. Date: Apr. 30, 2009

(54) Pattern Formation Method

(75) Inventors: Masako Kato, Yokohama (JP); Yoshihide Yamaguchi, Yokohama (JP); Takehiko Hasebe, Yokohama (JP); Masakazu Kishi, Ebina (JP); Tsuyoshi Yamaguchi, Ebina (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi Via Mechanics, Ltd., Ebina-shi (JP)

(21) Appl. No.: 12/260,546

(22) Filed: Oct. 29, 2008

(30) Foreign Application Priority Data
Oct. 30, 2007 (JP) 2007-282327
Oct. 17, 2008 (JP) 2008-268468

(51) Int. Cl. G03F 7/20

(52) U.S. Cl. 430/325

(57) ABSTRACT

The present invention provides a pattern formation method comprising a step of forming on a substrate a film of a first photosensitive material having low sensitivity to a light beam with a main wavelength at h-line emitted from a mask-less drawing exposure apparatus but having high sensitivity to an energy light beam containing ultraviolet light; a step of forming on the first photosensitive material a film of a second photosensitive material having higher sensitivity to a light beam with the main wavelength at h-line; a step of drawing a second pattern on the second photosensitive material with the mask-less direct drawing exposure apparatus; a step of developing the second photosensitive material; and a step of exposing to a light beam the second photosensitive material with the second pattern formed thereon and the first photosensitive material in batch to form a target first pattern on the first photosensitive material.

### BACKGROUND OF THE INVENTION

1. Field of the Invention

The present invention relates to a photolithography method. The invention more specifically to a pattern formation method for forming a pattern on a substrate by focusing a laser beam, for scanning, on a second photosensitive material formed on a first photosensitive material according to an exposed pattern for directly drawing and developing a second pattern, exposing the first photosensitive material in batch using the second pattern as a mask, then peeling off the second photosensitive material, and developing the first photosensitive material to form a first pattern as a solder resist on the substrate.

2. Description of the Related Art

A printed-wiring board is a component that forms an electronic circuit board by mounting electronic components such as a resistor or a capacitor thereon and connecting the components with wiring. The electronic components are mounted on a soldering land for a conductive circuit pattern, and the conductive circuit portion excluding the soldering land is coated with a solder resist as a permanent protective coat.

The solder resist prevents solder from depositing on portions not to be applied when an electronic component is soldered and also prevents a conductive circuit portion from being directly exposed to and oxidized by air. Furthermore, the solder resist plays roles of, for instance, improving electric properties and preserving insulation between conductors.

A material referred to as resist is used to coat a portion of a workpiece surface with a desired pattern so that only uncoated portions of the workpiece can be subjected to a subsequent processing. The resist used on a printed-wiring board is generally made of a photocurable resin having photosensitivity. Other types of resists include a solder resist used in soldering, a plating resist used in plating, and an etching resist used in etching.

In the conventional technique, a photosensitive liquid resist or a dry film resist is formed on a substrate and then the substrate is exposed to light via a photomask in order to form a pattern on various wiring boards such as printed-wring boards, semiconductors, and liquid crystal substrate.

In production of wiring boards, it is generally expected to provide high precision wiring products at a low cost within a short period of time. However, since it is often required to produce a variety of products each at a small lot or at a varying lot depending on the type of substrate, it is necessary to prepare a different mask for each production lot, which disadvantageously causes increase of cost and delay in product delivery. To overcome this drawback, there are strong demands for a technique enabling mask-less exposure which can satisfy all of the requirements for production of various types of products at a varying lot, high precision, and cost reduction at the same time.

In the mask-less exposure technique for directly drawing a pattern, it is not necessary to produce a photomask. Accordingly, it is possible not only to substantially save the cost for facility for manufacturing a mask and the material cost, but also to shorten the time it takes to manufacture the mask (lead time) for manufacture of a printed-wiring board. Furthermore, when the mask-less exposure technique for directly drawing a pattern is employed, it is possible to check distortion or warp of a board and correct a position of the board when the board is subjected to exposure. This advantageously enables positioning of the board with high precision.

In a first method of carrying out the mask-less exposure, a large output laser beam and a polygon mirror are used for scanning with the laser beam to directly draw a pattern on a board. This method is suitable for a case in which a relatively rough pattern is drawn in a large area, and can be carried out with a simple and low-cost apparatus (machine).

In a second method of carrying out the mask-less exposure, as described in JP-A-11-320968, a two-dimensional pattern is generated by using a two-dimensional spatial light modulation element such as a liquid crystal or a DMD (Digital Micro-Mirror Device), and the pattern is directly drawn on a board via a projection lens. In this method, it is possible to draw a fine pattern. In the two-dimensional drawing enabled by the two-dimensional light modulation as described above, when the light intensity is made higher, the drawing speed can be made further higher, and an optical system in which the light intensity is increased is proposed in JP-A-2002-182157 and JP-A-2004-157219).

In the first method, however, it is difficult to drawn a high-precision pattern in a large area. When the throughput is to be increased, a further larger output laser beam is required, resulting in increase of the apparatus cost as well as the running cost.

Durability or the operating life of the two-dimensional light modulation element used in the second method depends not only on intensity but also on a wavelength of incoming light. Therefore, in the range of light intensity which can be employed in the mask-less exposure technique, especially in the short wavelength range of incoming ultraviolet light (less than 400 nm), malfunctions or defects of light modulation elements occur more frequently, and sometimes the operating time until a fatal defect occurs will become disadvantageously shorter. To overcome this problem, when ultraviolet light is introduced into the two-dimensional light modulation element, it is necessary to limit the light intensity even if the exposure time becomes longer. Alternatively it is necessary to introduce visible light (in a wavelength range from 400 to 800 nm) or infrared light (with a wavelength of 800 nm or more) having a longer wavelength than ultraviolet light.

On the other hand, a mercury lamp used as a light source in the conventional exposure apparatus using a mask has bright lines of i-line (365 nm), h-line (405 nm), and g-line (436 nm) in the spectrum. Also a metal halide lamp often used in exposure of liquid resists is suitable for emitting light having a wavelength close to the i-line efficiently. A photosensitive material used in exposure technique for forming a wiring pattern is designed, from the viewpoints of its appropriateness for mass production and workability, so that the material becomes more sensitive as a wavelength of irradiating light becomes shorter and also so that the material becomes less sensitive in the wavelength area of visible light. Generally, when exposure is performed at the i-line which is a bright line of mercury, satisfactory patterning can be performed.

When mask-less exposure is performed, it is not impossible to use a mercury lamp as a light source, but it is difficult to efficiently obtain illumination light for exposure with high directivity from the mercury lamp.

In other words, not short-wavelength ultraviolet light but long-wavelength visible light is more suitable for an optical system for light modulation to be used for the mask-less exposure. Due to the problem as described above, it has been difficult to simultaneously achieve both improvement of exposure throughput and patterning with high precision in the conventional exposure technique.

Resists suitable for a mask-less exposure apparatus using a visible light source have been developed so as to improve throughput in the mask-less exposure. The resists have high sensitivity in the wavelength range from infrared light to visible light, and thereby even when the resists are applied to mask-less exposure, the satisfactory exposure throughput can be preserved. However, since the resists dedicated to the mask-less exposure performed by using a visible light source cannot be used in a yellow room which is used for resists photosensitive to the ordinary ultraviolet light, a dark room or a red room is required, and the conditions for mass production of wiring boards must be changed. In addition, the material cost is higher than general-purpose materials showing photosensitivity to ultraviolet light, and also the running cost is high.

The photosensitive materials showing the photosensitivity to visible light are not limited to the resists developed especially for the mask-less exposure using visible light. For instance, the photosensitive materials (referred to as silver halide material hereinafter) for silver salt photography containing a silver halide emulsion layer as disclosed in JP-A-2007-242371 or JP-A-2004-221564) can be used for patterning by exposure at a low dose rate even in a mask-less exposure apparatus using a visible light source. However, the photosensitive materials are shielding materials against electromagnetic waves or conductive materials for touch panels, and therefore cannot be used as a solder resist which is an insulating material for a printed-wiring board.

When used in a mask-less exposure apparatus for directly drawing a pattern using a semiconductor laser as a light source, the photosensitivity of the solder resist is substantially lower than those of other photosensitive materials such as a plating resist and an etching resist, and the exposure throughput is remarkably low.

Along with the recent tendency for size reduction and higher packaging density of electronic components, pad and pitch dimensions of a portion to be soldered have been becoming smaller year by year, and therefore such factors as the resolution or a positioning accuracy of a pattern to be formed between pads have been becoming more and more important during exposure of solder resists. To satisfy the requirements above, it has been desired to apply the technique of mask-less exposure to the solder resist exposure process.

If the sufficient hardness of a solder resist cannot be obtained during the exposure process of the solder resist, a surface of the solder resist is easily damaged by a developing solution during the development process after the exposure process, which may make it impossible to obtain necessary performances of the printed-wiring board. If printed-wiring boards are manufactured at a higher exposure dose rate, not only the exposure pattern will have a remarkably poor precision, but also the time it takes for the manufacturing step will become disadvantageously longer. This gives negative effects over the productivity. Therefore, there has been the strong need for an exposure method that ensures a high positioning precision even at a low exposure dose rate and also enables patterning with the high resolution.

### SUMMARY OF THE INVENTION

All of the related-art documents described above do not include a description concerning the technique for forming a pattern by exposing, at a high throughput, a solder resist having low sensitivity to visible light as a photosensitive material for a mask-less exposure apparatus (machine) irradiating with visible light.

An object of the present invention is to provide a pattern formation method enabling patterning at a high level of precision and high efficiency in an exposure process, in which the demands for cost reduction and order-to-delivery cycle time reduction are satisfied.

To achieve the object described above, the present invention provides a pattern formation method comprising: a film formation step of forming a film of a first photosensitive material on a substrate (board), the first photosensitive material having low sensitivity to visible light but having high sensitivity to an energy light beam containing ultraviolet light or near-ultraviolet light; a step of forming, on the film of the first photosensitive material, a film of a second photosensitive material having higher sensitivity to visible light than the first photosensitive material; a first exposure step of drawing a second pattern on the second photosensitive material with a mask-less direct drawing exposure apparatus for irradiating with exposure light containing the visible light; a first development step of forming the second pattern by processing the second photosensitive material with a pattern directly drawn thereon using a developing solution; a second exposure step of forming a first pattern by irradiating the film of the second photosensitive material formed on the first photosensitive material with the energy light beam containing ultraviolet or near-ultraviolet light beam in batch to transcribe the second pattern onto the first photosensitive material; a separation step of removing the second photosensitive material from the first photosensitive material exposed to light in the second exposure step; and a second development step of forming the first pattern by processing the first photosensitive material remaining after the separation step using a developing solution.

The first photosensitive material used in the pattern formation method according to the present invention comprises a photosensitive solder resist, while the second photosensitive material comprises a photosensitive material layer comprising a silver halide layer.

In other words, in the pattern formation method for forming a first pattern on a first photosensitive material having low sensitivity to exposure light which is a visible light used in a mask-less direct drawing exposure apparatus, the method is divided to a step of drawing a pattern on a second photosensitive material having high sensitivity to the visible light and formed on the first photosensitive material, and a step of irradiating with an energy light beam in batch to the first photosensitive material for optically hardening the photosensitive material. Thus, the time it takes for drawing a pattern can substantially be reduced.

As described above, the present invention was made of the finding by the present applicant that the problem of the low sensitivity of the first photosensitive material used as a solder resist to visible light as exposure light used in the mask-less direct drawing exposure apparatus can be solved by formation of a film of the second photosensitive material such as silver halide having high sensitivity to the visible light as exposure light on the first photosensitive material. This idea could not be anticipated by those skilled in the art, because the yellow room cannot be used and a dark room or a red room is required for the second photosensitive material having high sensitivity to visible light as exposure light, and also because changes of the manufacturing conditions are required at the site of mass production.

When the material not having the photosensitivity to light with the wavelength of 450 nm or more as disclosed, for instance, in JP-A-2003-77350) is used as the second photosensitive material in the present invention, it is possible to use the yellow room.

Layers of the first photosensitive material and the second photosensitive material are sequentially formed on the substrate. A photosensitive material having low sensitivity to a light beam from a mask-less direct drawing exposure apparatus is selected as the first photosensitive material, and a photosensitive material showing high sensitivity to the light source is selected as the second photosensitive material. The second photosensitive material comprises a not-photosensitive transparent film as a support body, and preferably the transparent film has a release-coated surface formed by release-coating. The transparent film functions to support a photosensitive material layer having high sensitivity to visible light exposed to the second photosensitive material (referred to as “highly sensitive photosensitive layer” hereinafter) and also to prevent a developing liquid for the highly sensitive photosensitive layer from contacting the first photosensitive material. The transparent film also functions to prevent mutual diffusion from causing cross-contamination between the highly sensitive photosensitive layer and the first photosensitive material and to prevent any change of photosensitivity of the photosensitive material. Furthermore the release-coated surface makes easier the separation of the second photosensitive material in the subsequent steps and also reduces damage to the first photosensitive material which may occur in the separation step. Because of the properties of the first photosensitive material, the release-coating step is not essential. It is desirable that the second photosensitive material having the layered structure comprising the release-coated surface, the transparent film, and the highly sensitive photosensitive layer laminated in this order can be formed on a substrate (board) with the film of the first photosensitive material formed thereon at a temperature of 70° C. or below such that the release-coated surface contacts the first photosensitive material. This requirement is for preventing the first photosensitive material from being thermally hardened. Light transmission of the release-coated surface and the transparent film (for all types of light from visible light to ultraviolet light) are desirably 90% or more.

For a light source of a mask-less exposure apparatus, a negative pattern of a desired pattern is directly drawn by means of the mask-less exposure apparatus. In this case, because the second photosensitive material is highly sensitive photosensitive, the exposure efficiency can substantially be improved as compared with the case where the pattern is directly drawn on first photosensitive material having low sensitivity. The present invention can advantageously be applied especially in exposure to a solder resist. The solder resist is applied to or laminated on the entire surface of the patterning surface of a printed-wiring board excluding soldering portions for mounting electronic components. Therefore, since when a negative type solder resist is exposed to a light beam by the method according to the present invention, a pattern is drawn which is a negative pattern of a desired pattern which covers the entire surface of a substrate (board), the area to be drawn can be reduced and the time it takes for drawing a pattern with the mask-less direct drawing exposure apparatus can further be reduced.

The photosensitivity of the first photosensitive material to visible light used as exposure light for a mask-less exposure apparatus is preferably half the second photosensitive material or below. In this context, the photosensitivity means a degree of hardening of the photosensitive material. It is desirable to optically harden the second photosensitive material with a mask-less exposure apparatus, and then perform to the operation for optically hardening the first photosensitive material at a light irradiation dose rate higher than the optimal exposure dose rate for drawing a pattern. This requirement is for preventing the first photosensitive material from being optically hardened when a pattern is drawing with the mask-less exposure apparatus. More specifically, the present invention is advantageously applied to photosensitive materials having extremely low sensitivity to visible light used as exposure light in the mask-less exposure apparatus.

The second photosensitive material is required to have the capability of changing light transmission after exposure for patterning and development. In other words, the second photosensitive material is required to have light transmission in the range from 30% to 70% to a light beam from a mask-less exposure apparatus in the period of time from a time point when the material is formed into a film until a time point when the material is exposed to the light beam, and also to have light transmission of 10% or below after exposure and development. The photosensitivity of the second photosensitive material itself is defined by a change rate of light transmission changing before and after pattern drawing with the mask-less exposure apparatus. In the method according to the present invention, when the second photosensitive material is developed, the drawn pattern shields the irradiated light beam. Therefore, when the entire pattern of the second photosensitive material and the first photosensitive material simultaneously are irradiated with a light beam, the second photosensitive material functions as a photomask, and the desired pattern which is reverse to the pattern directly drawn with the mask-less exposure apparatus is exposed on the first photosensitive material. By closely contacting the second photosensitive material to the first photosensitive material having low sensitivity to be processed, it is possible to expose the materials to exposure light without generating optical displacement such as diffraction, and also it is possible to exclude negative effects by oxidation causing a deterioration of photosensitivity of a photosensitive material.

When the first photosensitive material having low sensitivity is developed after the second photosensitive material is peeled off, the desired pattern is formed on the first photosensitive material. Because this pattern is drawn with the mask-less exposure apparatus, improvement of resolution can be expected.

According to the pattern formation method according to the present invention, a pattern can be drawn at a high precision and a high exposure efficiency with a mask-less exposure apparatus, which satisfies the requirements for cost reduction and shortening of time required until product delivery.

Furthermore, in the step of exposing a solder resist used in a printed wiring board to a light beam, it is possible to enabling high-precision positioning (aligning) and substantial shortening of the time it takes for patterning without spoiling the electric properties of the solder resist.

### BRIEF DESCRIPTION OF THE DRAWINGS

FIG. 1 is a flow chart showing a pattern formation method according to a first embodiment of the present invention;

P1 to P8 of FIG. 2 are views each illustrating a schematic cross section of a work shown in each of the process steps P1 to PB in FIG. 1; and

FIG. 3 is a graph illustrating behaviors of a highly sensitive photosensitive material layer and a first photosensitive material used in the pattern formation method according to the present invention during a hardening step by irradiating with a blue semiconductor laser beam with a main wavelength at h-line.

### DESCRIPTION OF THE PREFERRED EMBODIMENTS

A pattern formation method according to an embodiment of the present invention is described below, but the present invention is not limited to this embodiment.

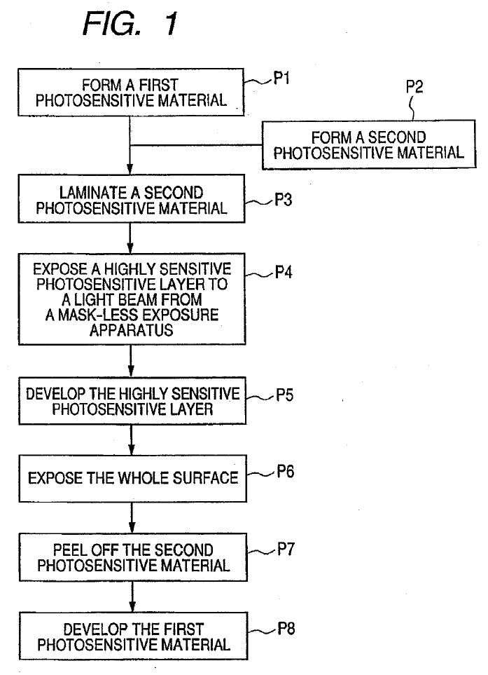

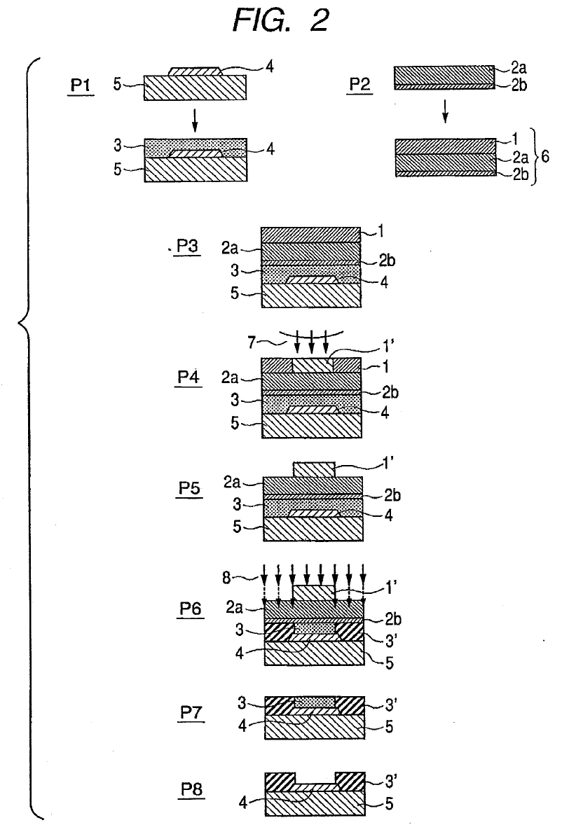

Outline of the embodiment of the present invention is described below with reference to FIG. 1 and FIG. 2 below.

The pattern formation method according to the present invention is performed as follows. A film of a first photosensitive material 3 is formed on a substrate 5 in a step p1. In a step P2, a highly sensitive photosensitive layer 1 (made of a photosensitive material for silver salt photography containing a silver halide emulsion layer) more sensitive than the first photosensitive material 3 is formed on a transparent film 2a having a release-coated surface 2b, but on a surface opposite to the release-coated surface 2b to form a second photosensitive material 6. In a step P3, the second photosensitive material 6 is laminated on the first photosensitive material 3 to form the highly sensitive photosensitive layer 1. In an exposure step P4, a mask-less direct drawing exposure apparatus 7 directly draws a pattern on the highly sensitive photosensitive layer 1. In this exposure step, the highly sensitive photosensitive layer 1 is irradiated with a blue semiconductor laser (not shown) with a main wavelength at h-line (wavelength: 405 nm) installed in the mask-less direct drawing exposure apparatus. A drawn pattern is formed by developing the highly sensitive photosensitive layer 1 in a step P5. In an exposure step P6, a drawing pattern 1′ formed on the highly sensitive photosensitive layer 1, the second photosensitive material 6, and the first photosensitive material 3 is subjected to exposure all at once. The pattern 1′ drawn on the highly sensitive photosensitive layer 1 and the second photosensitive material 6 are removed in a separation step P7. In a step P8, a reversed pattern 3′ (a target hardened solder resist pattern) of the drawn pattern 1′ is formed on the substrate 5 by developing the first photosensitive material 3.

Referring to P1 to P8 of FIG. 2, reference numeral 4 denotes a conductive portion formed on the substrate 5. Reference numeral 7 denotes a blue semiconductor laser beam whose visible light has a main wavelength at h-line (405 nm), which is emitted from a first light source for the mask-less direct drawing exposure apparatus used in the exposure step P4. Reference numeral 8 denotes a high-energy light beam containing ultraviolet or near-ultraviolet light emitted from a second light source used in the exposure step P6. The high-energy light beam has a spectrum with wavelengths ranging from 350 to 450 nm and the intensity in the range from 1% to 100% of all the energy to be emitted.

As the mask-less direct drawing exposure apparatus, it is possible to use, for instance, an apparatus in which a blue semiconductor laser emitting visible light is used as a first exposure light source and a pattern is directly drawn on a substrate by using an large output laser beam and a polygon mirror for scanning. Alternatively, it is possible to use an apparatus in which a two-dimensional pattern is generated by using a two-dimensional spatial light modulation element such as a liquid crystal device or a DMD (Digital Micro-Mirror Device) and the pattern is directly drawn via a projection lens onto a substrate.

Each of the steps above is described in detail below.

The first photosensitive material 3 used in the present invention is a photosensitive material for negative type i-line used in manufacturing printed-wiring boards. The first photosensitive material 3 is used in photolithographic process by irradiating with ultraviolet or near-ultraviolet light with wavelengths ranging from 350 to 450 nm in a manufacturing process of wiring boards. A type of the photosensitive material 3 to be used can be selected according to a purpose or an application. A solder resist used for coating a conductive circuit portion of a printed-wiring board excluding a soldering land as a permanent protection film is especially low in exposure efficiency for drawing a pattern with a mask-less exposure apparatus using a blue semiconductor laser as the first exposure light source, and thereby the advantageous effects provided by the present invention can easily be achieved.

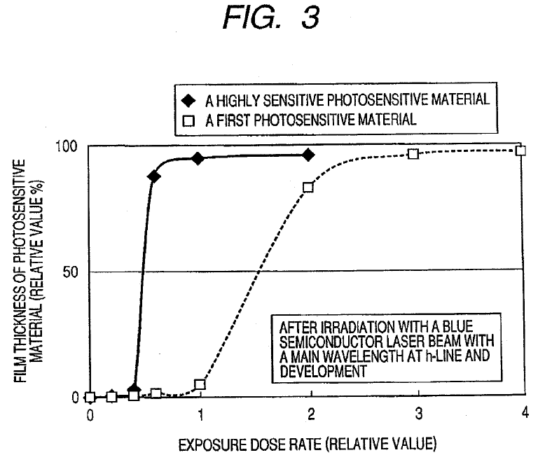

FIG. 3 is a graph describing an example of hardening behaviors (a relation between an exposure dose rate and a film thickness of a photosensitive material after development) when the highly sensitive photosensitive layer 1 and the first photosensitive material 3 used in the pattern formation method according to the present invention is irradiated with a blue semiconductor laser beam with a main wavelength at h-line (405 nm). The photosensitive material which can be used as the first photosensitive material 3 is a material that starts hardening when it is irradiated with a light beam at an exposure dose rate higher than that required to completely harden the highly sensitive photosensitive layer 1. In the exposure step P4, during the step of pattern drawing on the highly sensitive photosensitive layer 1, if photosensitivity of the first photosensitive material 3 is close to that of the highly sensitive photosensitive layer 1 when an emitted light beam passes through the transparent film 2a and the release-coated surface 2b each provided as an intermediate layer reaches a film of the first photosensitive material 3, the first photosensitive material 3 also is exposed to the light beam and is hardened.

In the present invention, because a pattern, which is a negative pattern of a desired final pattern in relation to the first photosensitive material 3, is drawn on the highly sensitive photosensitive layer 1 with the mask-less exposure apparatus in the exposure step P4, if also the first photosensitive material 3 is hardened when the highly sensitive photosensitive layer 1 is exposed to light, the desired final pattern may not be obtained. Therefore, in the exposure step P4, an exposure dose rate at the time point when hardening of the first photosensitive material 3 starts is required to be higher than that at the time point when hardening of the highly sensitive photosensitive layer 1 ends. Thus it is desirable that the photosensitivity of the first photosensitive material 3 to the exposure light beam (with a main wavelength at h-line) emitted from a first exposure light source for the mask-less exposure apparatus be higher two times or more than that of the highly sensitive photosensitive layer 1, and the larger the different is, the more the present invention can provide advantageous effects.

The first photosensitive material 3 used in the present invention may be either a dry film or a liquid on the condition that the material can be used to form a film on a surface of an object for exposure to a light beam such as a wiring board by any appropriate method. The method of forming a film of the first photosensitive material 3 on the substrate in the step P1 is not limited to any specific one, and when the first photosensitive material 3 is a film, such methods as laminating, or vacuum laminating may be employed. When the first photosensitive material 3 is a liquid, such methods as spray coating, roll coating, and spin-coating may be employed. A film thickness of the first photosensitive material 3 after formed into a film is preferably in the range from 2 μm to 100 μm, and the minimum processable dimension is about 1 μm. The photosensitive material 3 used in the present invention preferably contains an epoxy resin, an epoxy acrylate resin, or the like as main ingredients. It is needless to say that photosensitive materials other than those described above may be used depending on the structure or application of an object for exposure to a light beam.

For the formation of the second photosensitive material 6, the highly sensitive photosensitive layer 1 is formed on the transparent film 2a in the step P2. A method used is not limited to any specific one. When the highly sensitive photosensitive layer 1 is a film, such methods as laminating, or vacuum laminating may be employed. When the highly sensitive photosensitive layer 1 is a liquid, such methods as spray coating, roll coating, and spin-coating may be employed. A polymer film made of polyethylene telephthalate or polypropylene or the like may be used as the transparent film 2a. In the exposure step P4, if a pattern is directly drawn on the highly sensitive photosensitive layer 1, for instance, with the mask-less exposure apparatus using a blue semiconductor laser as a first exposure light source, the highly sensitive photosensitive layer 1 is required to be highly sensitive to irradiation with a light beam 7 with a main wavelength at h-line (405 nm) after formed into a film, and is also required to cause a change in light transmission for completely shielding a light beam after exposure and development to thereby fix a mask pattern 1′. If the first photosensitive material 3 is a negative type, either a negative reaction type or a positive reaction type can be applied to the highly sensitive photosensitive layer 1 regardless of the type. When the negative type photosensitive material is applied, a portion exposed to a light beam is hardened and a portion not exposed to the light beam dissolves when developed. When the positive type photosensitive material is applied, a portion exposed to a light beam dissolves when developed, and a portion not exposed to a light beam is hardened. Even if the highly sensitive photosensitive layer 1 is a negative type or positive type, the mask pattern 1′ reversed with respect to a desired pattern 3′ to be formed on the first photosensitive material 3 is directly drawn with the mask-less exposure apparatus in the exposure step P4.

Furthermore, there may be employed the technique in which the transparent film 2a is formed on the first photosensitive material 3 and then the highly sensitive photosensitive layer 1 is further formed on the transparent film 2a. However, preferably the second photosensitive material 6 is prepared separately and is formed into a film on the first photosensitive material 3 because damage to the first photosensitive material 3 can be reduced. Other method may be employed according to properties of the first photosensitive material 3.

The method of forming the film stack 6 on the first photosensitive material 3 in the step P3 is not limited to any specific one, and such methods as lamination or vacuum lamination may be employed. Temperature when the film stack 6 is formed is preferably 70° C. or below to prevent the first photosensitive material 3 from being thermally hardened. In this case, the temperature is not limited to the value above, and other temperature may be set according to properties of the first photosensitive material 3.

In the exposure step P4, the highly sensitive photosensitive layer 1 is directly drawn with a mask-less exposure apparatus. Then, in the step P5, a portion of the highly sensitive photosensitive layer 1 not having been exposed to a light beam is dissolved by a developing solution suitable for the highly sensitive photosensitive layer 1 to obtain the drawn mask pattern 1′. In this step, the transparent film 2a and the first photosensitive material 3 must adhere tightly to each other so that the developing solution will not contact the first photosensitive material 3. A type of the developing solution used should be selected according to a type of the photosensitive material used for the highly sensitive photosensitive layer 1.

The second light source used in the exposure step P6 can emit a high-energy light beam 8 containing ultraviolet or near-ultraviolet light with wavelengths ranging from 350 to 450 nm, and has an intensity corresponding to 1 to 100% of all the energy to be emitted. Specifically, it is preferable to use a discharge lamp such as a light source as a metal halide lamp, a low to ultrahigh voltage mercury lamp, a xenon lamp, or a halogen lamp, or to use a semiconductor laser light source or the like. Especially it is preferable to use a semiconductor laser in which it is easy to control the irradiation energy or a metal halide lamp which is inexpensive and for which maintenance is easy as long as the lamp used can uniformly illuminate a large area. Furthermore, other lamps may be selected according to an application or properties of the photosensitive material by taking into consideration such factors as power consumption and controllability over an irradiation dose rate, and also the lamps may be used in combination.

It is to be noted that, because positioning (aligning) operation is not required for the second light irradiation in the exposure step P6, irradiation of a light beam can be carried out in the state where an object for exposure to the light beam is not fixed or it is transported. More specifically, irradiation of the light beam may be carried out during transportation of the object for exposure. Thus the exposure time it takes for the second irradiation of a light beam from the second light source does not give any disadvantage over the throughput.

In the exposure step P6, after the entire surface of the first photosensitive material 3 using the drawn pattern 1′ as a mask is irradiated with a light beam to harden the first photosensitive material 3, and then the release-coated surface 2b, the transparent film 2a, and the drawn pattern 1′ are peeled off in the separation step P7. The separation method used is not limited to any specific one. In the step P8, a portion of the first photosensitive material 3 not having been exposed to a light beam is dissolved for example by using a developing solution suitable for the first photosensitive material 3 to obtain the reversed pattern 3′ on the substrate 5. If required, operations for thermally hardening or post-heating the object are performed to facilitate hardening of the target desired pattern 3′.

In the description above, it is assumed that the second photosensitive material 6 has a configuration comprising the highly sensitive photosensitive layer 1, the transparent film 2a, and the release-coated surface 2b. However, it is needless to say that only the highly sensitive photosensitive layer 1 may be formed as a second photosensitive material directly on the first photosensitive material 3, a pattern is directly drawn on the highly sensitive photosensitive layer 1, and unnecessary portions are removed.

### EXAMPLES

Examples of the pattern formation method according to the present invention are described below. An alkali-soluble negative type liquid photosensitive solder resist (produced by Hitachi Chemical Co., Ltd.: SR7200G) as a first photosensitive material 3 was applied, with a film thickness of about 25 μm, to a laminate sheet 5 with the both surfaces plated with copper and having a thickness of 0.5 mm to form an object for exposure to a light beam.

A highly sensitive photosensitive layer 1 is prepared by having silver bromide particles contained therein, with the silver bromide particle including a silver iodide of 5 mol % such that a volume ratio between the silver bromide particle and a gelatin solution is 0.6. The thus-formed highly sensitive photosensitive layer 1 is coated onto a polyethylene telephthalate (PET) film 2a with a thickness of 100 μm such that silver is deposited by 0.3 mol/m² to form a second photosensitive material 6. The second photosensitive material 6 was laminated on the solder resist layer at a temperature of 50° C.

In the exposure step P4, a pattern was drawn on the highly sensitive photosensitive layer 1 with a mask-less exposure apparatus by irradiating with a laser beam having the main wavelength at the h-line (wavelength: 405 nm) from a blue light-emitting semiconductor laser 7 functioning as a light source for the mask-less exposure apparatus at the exposure dose rates of 10, 20, and 30 mJ/cm². The exposure dose rates used in this embodiment are values measured with a UV-ray actinometer UV-M03A produced by ORC Manufacturing Co., Ltd. Then, in step P5, the pattern photosensitive layer 1 was developed with an alkaline solution and the pattern was fixed with an acidic solution. Then, in exposure step P6, the solder resist film and a pattern-forming section of the highly sensitive photosensitive layer 1 were irradiated with a light beam uniformly and simultaneously. In this embodiment, to harden the solder resist layer, the entire surface of the solder resist layer was irradiated with the high-energy light beam 8 containing ultraviolet light or near-ultraviolet light with wavelengths ranging from 350 to 450 nm emitted from a semiconductor laser light source at an exposure dose rate of 800 mJ/cm². In the separation step P7, the pattern-forming section of the highly sensitive photosensitive layer 1 and the PET film were peeled off from the solder resist layer. In step P8, development was performed with an aqueous solution of sodium carbonate with a concentration of 1% by weight at 30° C. to obtain a pattern 3′ which is reverse to the pattern drawn with the mask-less exposure apparatus.

The appearance of the via opening pattern formed on the solder resist layer was observed. The result is shown in Table 1. In Examples 1 to 3, only an exposure dose rate of a light beam with a main wavelength at h-line from the mask-less exposure apparatus was changed. Furthermore, in Comparative Examples 1 to 3, the highly sensitive photosensitive layer 1 was not provided, and the via pattern was directly drawn on the solder resist layer by changing the exposure dose rate of the light beam with a main wavelength at h-line. Data dimension for the drawn pattern diameter means data size of a via opening in test pattern data stored in the mask-less exposure apparatus. In Examples 1 to 3 and Comparative Examples 1 to 3, a via opening diameter actually provided in the solder resist layer was checked when a pattern data with a diameter of 70 μm was exposed to a laser beam.

TABLE 1

| | Direct drawing exposure with | | | | | |
|---|---|---|---|---|---|---|
| | mask-less exposure apparatus | | | | Actual opening diam- | |
| | Highly | | | | eter in an exposed | |
| | sensitive | | | Data dimension | potion of a solder | |
| | photosensi- | Exposure | | of drawn pattern | resist layer with a | |
| | tive layer | dose rate | | diameter | via diameter of 70 μm | |
| Example 1 | Present | 10 | mJ/cm² | 70 μm | 42.6 | μm |
| Example 2 | Present | 20 | mJ/cm² | 70 μm | 56.8 | μm |
| Example 3 | Present | 30 | mJ/cm² | 70 μm | 51.7 | μm |
| Comparative | Not present | 30 | mJ/cm² | 70 μm | Completely dissolved | |
| example 1 | | | | | and no pattern left | |
| Comparative | Not present | 500 | mJ/cm² | 70 μm | Not opened | |
| example 2 | | | | | | |
| Comparative | Not present | 800 | mJ/cm² | 70 μm | 53.1 | μm |
| example 3 | | | | | | |

AS shown in Example 1, the exposure dose rate of 10 was short and the actual opening diameter was a little smaller. This fact indicates that, when a pattern is drawn on the highly sensitive photosensitive layer 1 at this level of exposure dose rate, an amount of deposited silver is insufficient for forming a pattern on the solder resist layer. However, when the exposure dose rate was 20 mJ/cm² as in Example 2, an adequate dimension of the opening diameter was obtained with no defect (perfect circle in the case of a via form). Also when the exposure dose rate was 30 mJ/cm², a satisfactory pattern form was obtained (Example 3). When the exposure dose rate was 40 mJ/cm² or more, the exposure dose rate was excessive and a pattern could not be drawn on the highly sensitive photosensitive layer 1 itself. Therefore, the exposure dose rate of 20 mJ/cm² is optimal from the view point of an actual opening diameter. However, when it is taken into consideration that a higher exposure dose rate is advantageous for hardening the silver halide layer (resistance to a developing solution, a remaining film thickness, or the like), the exposure dose rate is preferably in the range from 20 to 30 mJ/cm². That is, the present invention is characterized in that an exposure dose rate with a mask-less exposure apparatus is controlled, for instance, to a range from 20 to 30 mJ/cm².

On the other hand, when a silver halide layer is not used and the solder resist is exposed to a laser beam only with a mask-less exposure apparatus for irradiating with a laser beam with a main wavelength at h-line as shown in Comparative Examples, because the solder resist layer has low sensitivity to the light beam with the main wavelength at h-line, the solder resist is not hardened at all when the exposure dose rate is 30 mJ/cm² as shown in Comparative Example 1, and all of the solder resist was dissolved in the development step. When the exposure dose rate is made higher up to 500 mJ/cm² as shown in Comparative Example 2, the solder resist is hardened and a an opening is obtained when the data dimension for the pattern diameter is as large as 500 μm, but in the case of a small via form with a data dimension of, for instance, 70 μm, its form collapses when developed due to shortage of the exposure dose rate, and a target desired pattern form cannot be obtained. To obtain an actual dimension of an opening with not defect like that obtained by using the highly sensitive photosensitive layer 1, the solder resist layer has low sensitivity to a light beam with the main wavelength at h-line, the exposure dose rate as high as 800 mJ/cm² is required as shown in Comparative Example 3.

As shown above, with the embodiment of the present invention as described above, exposure dose rate of a light beam with a main wavelength at h-line used for patterning with a mask-less exposure apparatus can be reduced to at a level of 20 to 30 mJ/cm². Further, negative and positive portions of a pattern to be drawn with the mask-less exposure apparatus are inverted previously so that a desired pattern can be obtained. Furthermore, with the embodiment of the present invention described above, the time it takes to draw a pattern on a highly sensitive photosensitive layer with the mask-less exposure apparatus can be reduced to 1/15 to 1/10 of that when a pattern is directly drawn on a solder resist layer.

Another embodiment of the present invention is described below. An alkali-soluble negative photosensitive solder resist in the liquid state (produced by Taiyo Ink MFG Co., Ltd.: PSR-4000 AUS300) was applied with a thickness of about 25 μm as the first photosensitive material 3 to a 0.8 mm-thick laminate sheet 5 with the both surfaces coated with copper (produced by Hitachi Chemical Co., Ltd.: MCL-E-67) to prepare a material to be exposed to a light beam. Furthermore, the second photosensitive material 6 (produced by KONICA MINOLTA MG Co., Ltd.: CUHE-100E) prepared by applying a gelatin solution containing silver halide to a polyethylene telephthalate (PET) film 2a with a thickness of 100 μm was laminated, as the highly sensitive photosensitive layer 1, on the solder resist layer at 50° C.

In the exposure step P4, a pattern was drawn on the highly sensitive photosensitive layer 1 with a mask-less exposure apparatus by irradiating with a laser beam having a main wavelength at h-line (wavelength: 405 nm) from the blue light-emitting semiconductor laser 7 functioning as a light source for the mask-less exposure apparatus at the exposure dose rates of 20, 30, and 40 mJ/cm². The exposure dose rates used in this embodiment are values measured with a UV-ray actinometer UV-M03A produced by ORC Manufacturing Co., Ltd. Then, in step P5, the pattern photosensitive layer 1 was developed with an alkaline solution (produced by KONICA MINOLTA MG Co, Ltd.: CDM-681) and the pattern was fixed with an acidic solution (produced by KONICA MINOLTA MG Co., Ltd.: CFL-881). Then, in exposure step P6, the solder resist film and a pattern-forming section of the highly sensitive photosensitive layer 1 were irradiated with a light beam uniformly and simultaneously. In this embodiment, to harden the solder resist layer, the entire surface of the solder resist layer was irradiated in batch with the high-energy light beam 8 containing ultraviolet light or near-ultraviolet light with a wavelength in the range from 350 to 450 nm, which is emitted by a ultra-high voltage UV (Ultra Violet) lamp (produced by Ushio, Inc.: USH-500D), at an exposure dose rate of 500 mJ/cm². In the separation step P7, the pattern-forming section of the highly sensitive photosensitive layer 1 and the PET film were peeled off from the solder resist layer. In step P8, development was performed with an aqueous solution of sodium carbonate with a concentration of 1% by weight at 30° C. to obtain a pattern 3′ in which the negative portions and positive portions were inverted from those of the pattern drawn with the mask-less exposure apparatus.

The appearance of the via opening pattern formed on the solder resist layer was observed. The result is shown in Table 2. In Examples 4 to 6, only an exposure dose rate of a light beam with a main wavelength at h-line from the mask-less exposure apparatus was changed. Furthermore, in Comparative Examples 4 to 7, the highly sensitive photosensitive layer 1 was not provided, and the via pattern was directly drawn on the solder resist layer by changing the exposure dose rate of the light beam with a main wavelength at h-line. Data dimension for the drawn pattern diameter means data size of a via opening in test pattern data stored in the mask-less exposure apparatus. In Examples 4 to 6 and Comparative Examples 4 to 7, a via opening diameter actually provided in the solder resist layer was checked when a pattern data with a diameter of 150 μm was exposed to a laser beam.

TABLE 2

| | Direct drawing exposure with | | | | |
|---|---|---|---|---|---|
| | mask-less exposure apparatus | | | | Actual opening diam- |
| | Highly | | | | eter in an exposed |
| | sensitive | | | Data dimension | potion of a solder |
| | photosensi- | Exposure | | of drawn pattern | resist layer with a |
| | tive layer | dose rate | | diameter | via diameter of 150 μm |
| Example 4 | Present | 20 | mJ/cm² | 150 μm | 128.2 μm |
| Example 5 | Present | 30 | mJ/cm² | 150 μm | 143.0 μm |
| Example 6 | Present | 40 | mJ/cm² | 150 μm | 145.7 μm |
| Com. E. 4 | Not present | 30 | mJ/cm² | 150 μm | Completely dissolved |
| | | | | | and no pattern left |
| Com. E. 5 | Not present | 1000 | mJ/cm² | 150 μm | Not opened |
| Com. E. 6 | Not present | 1500 | mJ/cm² | 150 μm | 127.8 μm |
| Com. E. 7 | Not present | 2000 | mJ/cm² | 150 μm | 120.5 μm |

As shown in Example 4, when the exposure dose rate was 20 mJ/cm², the actual dimension of the opening diameter was slightly smaller due to insufficient exposure. This fact indicates that, at this level of exposure dose rate, even though a pattern is drawn on the highly sensitive photosensitive layer 1, the quantity of deposited silver is short to form a pattern on the solder resist layer. However, when the exposure dose rate was 30 mJ/cm² as shown in Example 5, a sufficient opening diameter was obtained with no defect (nearly a perfect circle in the case of a via-shape). Also when the exposure dose rate was 40 mJ/cm², an excellent pattern was formed (Example 6). When the exposure dose rate was 50 mJ/cm² or more, the exposure dose rate was excessive and a diameter of the opening on the highly sensitive photosensitive layer 1 became larger, and also a diameter of an opening on the solder resist layer became larger accordingly. Therefore, when determined only based on the actual dimension of each opening, the exposure dose rate of 30 mJ/cm² is optimal. However, when it is taken into consideration that a higher exposure dose rate is more advantageous for improvement of a degree of hardness of the highly sensitive photosensitive layer 1 (or such parameters as a resistance to a development solution or a thickness of a residual film), the exposure dose rate in the range from 30 to 40 mJ/cm² is preferable. In other words, the present invention is characterized in that the exposure dose rate with a mask-less exposure apparatus is adjusted, for instance, in the range from 30 to 40 mJ/cm².

On the other hand, when the solder resist was exposed, without using the highly sensitive photosensitive layer 1, to a light beam from a mask-less exposure apparatus irradiating with a light beam with a main wavelength at h-line as shown in Comparative Examples 4 to 7, because the solder resist has low sensitivity to the light beam with a main wavelength at h-line, the solder resist did not harden at all at an exposure dose rate of 30 mJ/cm² as shown in Comparative Example 4. As a result, all of the solder resist was dissolved during the development process. Furthermore, when the exposure dose rate was raised up to 1000 mJ/cm² as shown in Comparative Example 5, the solder resist hardened and an opening was obtained in a large via-shape with a large pattern diameter of, for instance, 500 μm. However, in the case of a small via-shape with a small pattern diameter of, for instance, 150 μm, the exposure dose rate was short with the form collapsed during the development process, so that the target desired pattern form could not be achieved. As shown in Comparative Example 6, when the exposure dose rate as large as 1500 mJ/cm² was applied, a via-shape with a pattern diameter of 150 μm could be opened, but the opening diameter substantially equivalent to that which could be achieved when the highly sensitive photosensitive layer 1 was present could not be achieved without defect. When the exposure doze rate was further raised as shown in Comparative Example 7, a diameter of the opening became smaller due to excessive light. If the highly sensitive photosensitive layer 1 was not used, the maximum opening diameter is obtained at an exposure dose rate of 1500 mJ/cm², and is substantially equal to that obtained in Example 1. That is, when the highly sensitive photosensitive layer 1 is used in the exposure process, the solder resist having an improved resolution is provided.

As shown above, with the embodiment of the present invention as described above, exposure dose rate of a light beam of a blue semiconductor laser with a main wavelength at h-line for patterning with a mask-less exposure apparatus can be reduced to at a level of 30 to 40 mJ/cm². Further, negative and positive portions of a pattern to be drawn with the mask-less exposure apparatus are inverted previously so that a desired pattern can be obtained. Furthermore, with the embodiment of the present invention described above, the time it takes to draw a pattern on a highly sensitive photosensitive layer 1 with the mask-less exposure apparatus can be reduced to 1/20 of that when a pattern is directly drawn on a solder resist layer.

What is claimed is:

1. A pattern formation method comprising:
a film formation step of forming a film of a first photosensitive material on a substrate, the first photosensitive material having low sensitivity to visible light but having high sensitivity to an energy light beam containing ultraviolet light or near-ultraviolet light;
a step of forming, on the film of the first photosensitive material, a film of a second photosensitive material having higher sensitivity to visible light than the first photosensitive material;
a first exposure step of drawing a second pattern on the second photosensitive material with a mask-less direct drawing exposure apparatus for irradiating with exposure light containing the visible light;
a first development step of forming the second pattern by processing the second photosensitive material with a pattern directly drawn thereon using a developing solution;
a second exposure step of forming a first pattern by irradiating the film of the second photosensitive material formed on the first photosensitive material with the energy light beam containing ultraviolet or near-ultraviolet light beam in batch to transcribe the second pattern onto the first photosensitive material;
a separation step of removing the second photosensitive material from the first photosensitive material exposed to light in the second exposure step; and
a second development step of forming the first pattern by processing the first photosensitive material remaining after the separation step using a developing solution.

2. The pattern formation method according to claim 1, wherein the first photosensitive material comprises a photosensitive solder resist, and the second photosensitive material has a photosensitive material layer comprising a silver halide layer.

3. The pattern formation method according to claim 1, wherein a surface of the film of the second photosensitive material formed on the first photosensitive material in the second exposure step is uniformly irradiated with an energy light beam containing ultraviolet or near-ultraviolet light.

4. The pattern formation method according to claim 1, wherein a reaction type of the first photosensitive material is a negative one, and a reaction type of the second photosensitive material is a negative one.

5. The pattern formation method according to claim 1, wherein a reaction type of the first photosensitive material is a negative one, and a reaction type of the second photosensitive material is a positive one.

6. The pattern formation method according to claim 1, wherein the second photosensitive material has the laminated configuration having a photosensitive material layer formed on a support body and having high sensitivity to visible light and a release-coated surface subjected to release-coating on a surface opposite to the support body.

7. The pattern formation method according to claim 6, wherein the release-coated surface can be formed on the substrate with the first photosensitive material film formed thereon at a temperature of 70° C. or below.

8. The pattern formation method according to claim 6, wherein the support body and the release-coated surface are made of a material which is transparent and not photosensitive.

9. The pattern formation method according to claim 1, wherein, when the energy light beam containing ultraviolet or near-ultraviolet light is irradiated in batch in the second exposure step, the second pattern formed on the second photosensitive material in the first development step functions as a mask pattern.

10. The pattern formation method according to claim 1, wherein, when the second pattern is drawn on the second photosensitive material in the first exposure step, an irradiation dose rate of the exposure light containing visible light to the second photosensitive material is controlled before the first photosensitive material reacts with exposure light and starts hardening.

11. The pattern formation method according to claim 2, wherein a surface of the film of the second photosensitive material formed on the first photosensitive material in the second exposure step is uniformly irradiated with an energy light beam containing ultraviolet or near-ultraviolet light.

12. The pattern formation method according to claim 2, wherein a reaction type of the first photosensitive material is a negative one, and a reaction type of the second photosensitive material is a negative one.

13. The pattern formation method according to claim 2, wherein a reaction type of the first photosensitive material is a negative one, and a reaction type of the second photosensitive material is a positive one.

14. The pattern formation method according to claim 2, wherein the second photosensitive material has the laminated configuration having a photosensitive material layer formed on a support body and having high sensitivity to visible light and a release-coated surface subjected to release-coating on a surface opposite to the support body.

15. The pattern formation method according to claim 2, wherein, when the energy light beam containing ultraviolet or near-ultraviolet light is irradiated in batch in the second exposure step, the second pattern formed on the second photosensitive material in the first development step functions as a mask pattern.

16. The pattern formation method according to claim 2, wherein, when the second pattern is drawn on the second photosensitive material in the first exposure step, an irradiation dose rate of the exposure light containing visible light to the second photosensitive material is controlled before the first photosensitive material reacts with exposure light and starts hardening.
